(19) United States
(12) Patent Application Publication
(10) Pub. No.: US 2026/0211065 A1
(43) Pub. Date: Jul. 23, 2026

(54) MAGNETIC SENSOR MODULE AND MAGNETIC-FIELD CORRECTION METHOD

(71) Applicant: HAMAMATSU PHOTONICS K.K., Hamamatsu-shi (JP)

(72) Inventors: Kosuke ICHIMURA, Shizuoka (JP); Masaki YAMADA, Shizuoka (JP)

(73) Assignee: HAMAMATSU PHOTONICS K.K., Hamamatsu-shi (JP)

(21) Appl. No.: 19/437,594

(22) Filed: Dec. 31, 2025

(30) Foreign Application Priority Data
Jan. 20, 2025 (JP) 2025-007578

(51) Int. Cl. G01R 33/26

(52) U.S. Cl. CPC G01R 33/26

(57) ABSTRACT

A magnetic sensor module includes a photodiode configured to detect pump light passing through a cell, a magnetic-field correction unit configured to correct a magnetic field within the cell, and a control circuit configured to execute a correction process for applying a correction magnetic field to the magnetic field within the cell. In the correction process, the control circuit acquires at least two intensities among first, second, and third detection intensities of magnetic fields in X-, Y-, and Z-axis directions. When one of two intensities among correction intensities of the magnetic fields in the X-, Y-, and Z-axis directions is changed, the control circuit adjusts one of the correction intensities to reduce the change in the detection intensity in a direction corresponding to the other of the two intensities.

### TECHNICAL FIELD

Aspects of embodiments relate to a magnetic sensor module and a magnetic-field correction method.

### BACKGROUND

Conventionally, a magnetic sensor module including a cell in which an alkali metal is sealed, a laser light source configured to emit laser light toward the cell, a light detection unit configured to detect the laser light that has passed through the cell, a magnetic-field correction unit configured to correct a magnetic field within the cell, and a control unit configured to detect the magnetic field based on an electrical signal from the light detection unit and execute a correction process by controlling the magnetic-field correction unit to apply a correction magnetic field to the magnetic field within the cell is known (e.g., see the following Non-Patent Literature 1).

[Non-Patent Literature 1] Yan, Y et al., “Analysis and Correction of the Crosstalk Effect in a Three-Axis SERF Atomic Magnetometer,” Photonics 2022, 9, 654.

### SUMMARY

In the magnetic sensor module as described above, when the magnetic-field correction unit is controlled to apply a correction magnetic field to the magnetic field within the cell, a magnetic field of a component of a predetermined direction included in the correction magnetic field sometimes leaks into another direction orthogonal to the predetermined direction. Such leakage of the magnetic field of the component of the predetermined direction has been a cause of an error when the magnetic field is detected based on the electrical signal from the light detection unit.

For example, the magnetic-field correction unit may include a correction coil for correcting a magnetic field of a component of a predetermined direction included in a magnetic field within the cell. In this case, to suppress an influence of a magnetic field from an external environment when detecting magnetism of a measurement target, when an electric current to be supplied to the correction coil is controlled so that the magnetic field of the component of the predetermined direction within the cell is zero, the magnetic field generated by the correction coil becomes a magnetic field that includes only the magnetic field of the component of the predetermined direction at a central portion of the correction coil, while the magnetic field generated by the correction coil becomes a magnetic field that includes the magnetic field of the component of the predetermined direction and a magnetic field of a component of another direction orthogonal to the predetermined direction at both end portions of the correction coil. In this way, the magnetic field generated by the correction coil leaks from the predetermined direction to the other direction orthogonal to the predetermined direction. As a result, the detection accuracy of the magnetic field of the component of the other direction included in the magnetic field within the cell is degraded.

Therefore, an aspect of the present embodiment has been made in view of such problems, and an objective thereof is to provide a magnetic sensor module and a magnetic-field correction method that enable the accurate detection of a magnetic field within a cell.

According to a first aspect of an embodiment, there is provided a magnetic sensor module comprising: a cell in which an alkali metal is sealed; a laser light source configured to emit laser light along a first direction toward the cell; a light detection unit configured to detect the laser light that has passed through the cell; a magnetic-field correction unit configured to correct a magnetic field within the cell; and a control unit configured to acquire an intensity of the magnetic field within the cell in at least two of the first direction, a second direction orthogonal to the first direction, and a third direction orthogonal to both the first and second directions and execute a correction process by controlling the magnetic-field correction unit to apply a correction magnetic field to the magnetic field, based on an electrical signal from the light detection unit, wherein the control unit acquires at least two of a first detection intensity of the magnetic field in the first direction, a second detection intensity of the magnetic field in the second direction, and a third detection intensity of the magnetic field in the third direction based on the electrical signal from the light detection unit in the correction process, and wherein, when one of any two intensities among a first correction intensity of the magnetic field in the first direction, a second correction intensity of the magnetic field in the second direction, and a third correction intensity of the magnetic field in the third direction is changed in the correction process, the control unit controls the magnetic-field correction unit to apply the correction magnetic field so that any one of the first correction intensity, the second correction intensity, and the third correction intensity is adjusted to reduce a change in the detection intensity in a direction corresponding to the other of the two intensities.

Alternatively, according to a second aspect of the embodiment, there is provided a magnetic-field correction method of a magnetic sensor module including a cell in which an alkali metal is sealed, a laser light source configured to emit laser light along a first direction toward the cell, a light detection unit configured to detect the laser light that has passed through the cell, and a magnetic-field correction unit configured to correct a magnetic field within the cell, the magnetic-field correction method comprising: a correction step of acquiring an intensity of the magnetic field within the cell in at least two of the first direction, a second direction orthogonal to the first direction, and a third direction orthogonal to both the first and second directions and executing a correction process by controlling the magnetic-field correction unit to apply a correction magnetic field to the magnetic field, based on an electrical signal from the light detection unit, wherein the correction step includes acquiring at least two of a first detection intensity of the magnetic field in the first direction, a second detection intensity of the magnetic field in the second direction, and a third detection intensity of the magnetic field in the third direction based on the electrical signal from the light detection unit, and applying, when one of any two intensities among a first correction intensity of the magnetic field in the first direction, a second correction intensity of the magnetic field in the second direction, and a third correction intensity of the magnetic field in the third direction is changed, the correction magnetic field so that any one of the first correction intensity, the second correction intensity, and the third correction intensity is adjusted to reduce a change in the detection intensity in a direction corresponding to the other of the two intensities.

According to the above-described first and second aspects, when one of any two intensities among the first correction intensity, the second correction intensity, and the third correction intensity is changed, the correction magnetic field is applied so that any one of the first correction intensity, the second correction intensity, and the third correction intensity is adjusted to reduce a change in the detection intensity corresponding to the other of the two intensities. Thereby, the magnetic field of the component of the predetermined direction included in the correction magnetic field can reduce an amount of leakage in another direction orthogonal to the predetermined direction. For example, when the second correction intensity is changed, the correction magnetic field is applied so that the first correction intensity is adjusted to reduce the change in the third detection intensity. In this case, it is possible to reduce the amount of leakage of the magnetic field of the component of the predetermined direction included in the correction magnetic field into another direction and the amount of leakage of the magnetic field of the component of another direction included in the correction magnetic field into the predetermined direction. Thereby, it is possible to accurately detect the magnetic field within the cell.

### BRIEF DESCRIPTION OF THE DRAWINGS

FIG. 1 is a block diagram showing a magnetic detection system including a magnetic sensor module according to a first embodiment.

FIG. 2 is a schematic configuration diagram of the magnetic sensor module of FIG. 1.

FIG. 3 is a flowchart showing an example of a process of a magnetic-field detection method including a magnetic-field correction method according to the first embodiment.

FIGS. 4A and 4C are graphs showing a second modulation signal applied to a second correction coil of a magnetic-field correction unit shown in FIG. 1. FIGS. 4B and 4D are graphs showing a third modulation signal applied to a third correction coil of the magnetic-field correction unit.

FIG. 5A is a graph showing a spectral waveform of an electrical signal output from a light detection unit shown in FIG. 1, FIG. 5B is a graph showing a second detection intensity shown in FIG. 1, and FIG. 5C is a graph showing a third detection intensity.

FIG. 6A is a graph showing a relationship between an evaluation value of leakage of a magnetic field of a component of a Z-axis direction included in a correction magnetic field into a Y direction and a first detection intensity, FIG. 6B is a graph showing a variation of the first detection intensity over time, and FIG. 6C is a graph showing a variation of the above-described evaluation value over time.

FIGS. 7A and 7B are explanatory diagrams of operational effects produced by the magnetic sensor module according to the first embodiment.

FIG. 8 is a flowchart showing an example of a process of a magnetic-field detection method including a magnetic-field correction method according to a second embodiment.

FIG. 9A is a graph showing a relationship between a second detection intensity or a third detection intensity and an amount of transmitted light of a laser passing through the cell, and FIG. 9B is a graph showing a relationship between the first detection intensity and the amount of transmitted light of the laser passing through the cell.

FIG. 10A is a graph showing a relationship between an evaluation value of leakage of a magnetic field of a component of the Y-axis direction included in the correction magnetic field into another direction and the first detection intensity, FIG. 10B is a graph showing a relationship between an evaluation value of leakage of a magnetic field of a component of the Z-axis direction included in the correction magnetic field into another direction and the first detection intensity, and FIG. 10C is a graph showing a relationship between an evaluation value of leakage of a magnetic field of a component of an X-axis direction included in the correction magnetic field into another direction and the first detection intensity.

### DETAILED DESCRIPTION

Embodiments of the present invention will be described in detail below with reference to the accompanying drawings. Also, in the description, the same reference signs denote the same elements and elements having the same functions, and redundant description thereof will be omitted.

### First Embodiment

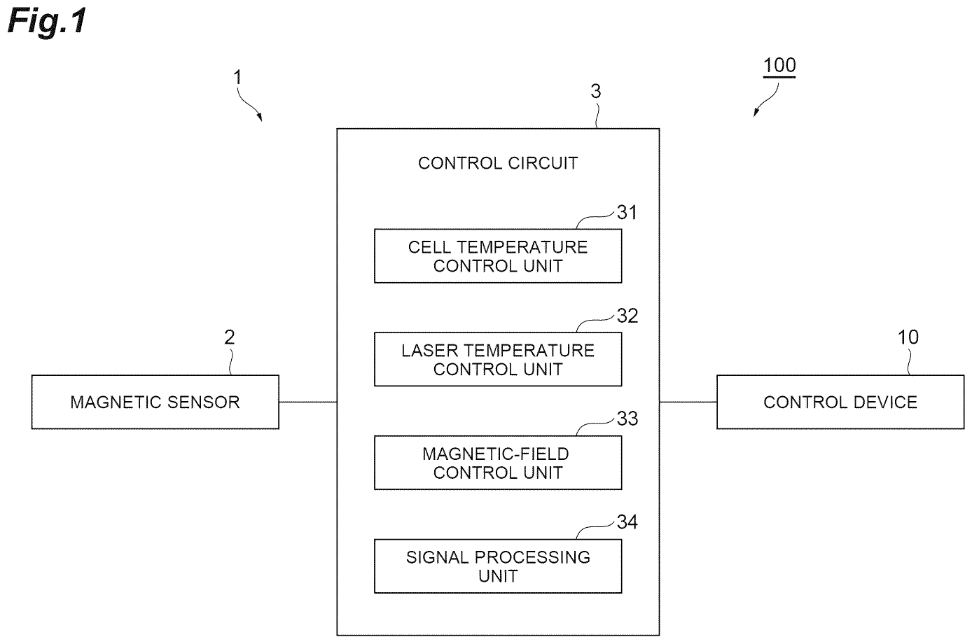

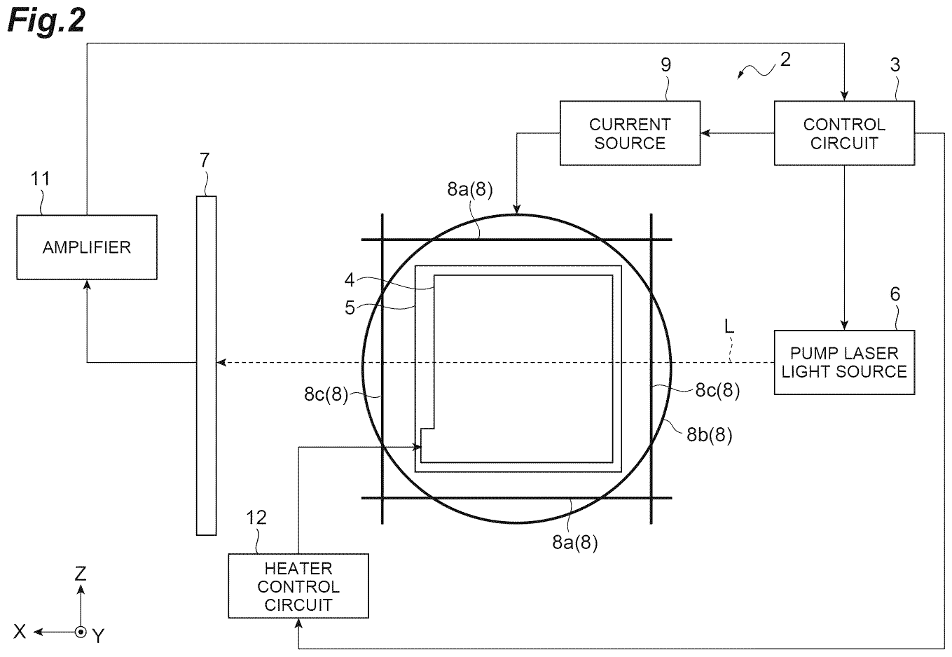

FIG. 1 is a block diagram showing a magnetic detection system with a magnetic sensor module according to a first embodiment. FIG. 2 is a schematic configuration diagram showing the magnetic sensor module according to the first embodiment. The magnetic sensor module 1 is a device that measures a magnetic field using optical pumping. The magnetic sensor module 1 may be used for the purpose of biological measurement using magnetoencephalography, magnetospinography, or the like or the purpose of material analysis using nuclear magnetic resonance (NMR)), but the purpose of use is not limited thereto. In FIG. 2, the X-axis is defined along an incidence direction of pump light for a cell to be described below, the Y-axis is defined in a direction perpendicular to the X-axis, and the Z-axis is defined in a direction perpendicular to both the X-axis and the Y-axis. Moreover, in FIG. 1, a propagation path of light is indicated by a dotted line, while transmission paths of power and signals are indicated by solid lines with arrows.

As shown in FIG. 1, the magnetic detection system 100 includes a magnetic sensor module 1 and a control device 10. The magnetic sensor module 1 includes a magnetic sensor 2 and a control circuit 3 (control unit). The control device 10 controls the operation of the magnetic sensor 2 by controlling the control circuit 3. The control device 10 may be, for example, a PC, a microcontroller unit (MCU), or the like. The control circuit 3 is a drive board for driving the magnetic sensor 2, and is, for example, a circuit of an MCU, a field programmable gate array (FPGA), and the like. The control circuit 3 may also be integrated with the control device 10, and, in this case, the magnetic detection system 100 can be regarded as the magnetic sensor module 1.

As shown in FIG. 2, the magnetic sensor 2 includes a cell 4, a heater 5, a pump laser light source (laser light source) 6, a photodiode (light detection unit) 7, a magnetic-field correction unit 8, a current source 9, an amplifier 11, and a heater control circuit 12. The details of each constituent element of the magnetic sensor module 1 will be described below.

The cell 4 has, for example, a substantially rectangular-parallelepiped and bottomed cylindrical shape, and is formed of a material that has light transmission with respect to pump light L to be described below. Examples of the material of the cell 4 include quartz, sapphire, silicon, Kovar glass, borosilicate glass, and the like. The cell 4 accommodates an alkali metal and a sealed gas. The alkali metal sealed in the cell 4, for example, may be at least one of lithium (Li), sodium (Na), potassium (K), rubidium (Rb), and cesium (Cs). Moreover, the sealed gas protects the alkali metal vapor and suppresses noisy light emission. The sealed gas may be, for example, at least one of inert gases of helium (He), neon (Ne), argon (Ar), krypton (Kr), xenon (Xe), nitrogen (N2), and the like.

The heater 5 is provided adjacent to the cell 4 and heats the interior of the cell 4. The heater 5 generates heat in accordance with an electric current supplied from a heater control circuit 12 to be described below. In the heater 5, based on a measurement signal from a temperature sensor (not shown) that measures an internal temperature of the cell 4, the supply current from the heater control circuit 12 is controlled so that the internal temperature of the cell 4 reaches a predetermined temperature (e.g., 180° C.), such that the alkali metal is vaporized within the cell 4 and a vapor density is controlled.

The pump laser light source 6 emits the pump light L (laser light) toward the interior of the cell 4 along the X-axis direction (first direction). The pump laser light source 6 emits the pump light L, which excites the atoms of the alkali metal, in a circularly polarized state. The pump laser light source 6 may shape the pump light L to any desired size. The atoms of the alkali metal accommodated in the cell 4 are excited by the pump light L. A wavelength of the pump light L is set in accordance with a type of atom (more specifically, an absorption line wavelength) constituting the vapor of the alkali metal, and, for example, is set to match an absorption wavelength of the alkali metal. In the first embodiment, a drive condition of the pump laser light source 6 is determined by the control circuit 3, and an intensity and wavelength of the pump light L emitted from the pump laser light source 6 can be adjusted by a control process of the control circuit 3 (details will be described below). To implement this control, the pump laser light source 6 has a function in which the oscillation wavelength can be controlled using an external resonator or a wavelength control function of a configuration in which an oscillation wavelength can be controlled by controlling a temperature of a laser element or the like.

The photodiode 7 is a detection unit that detects the pump light L having passed through the interior of the cell 4, from outside the cell 4. The pump light L transmitted through the interior of the cell 4 is incident on the photodiode 7. The photodiode 7 generates and outputs an electrical signal according to a frequency distribution of the intensity of the pump light L. The amplifier 11 amplifies the electrical signal output from the photodiode 7 as a pump light intensity signal obtained by detecting the intensity of the pump light L transmitted through the cell 4 and generates the amplified pump light intensity signal. The amplifier 11 outputs the amplified pump light intensity signal to the control circuit 3.

The magnetic-field correction unit 8 corrects the magnetic field within the cell 4. Specifically, the magnetic-field correction unit 8 is provided near the cell 4, and is a group of coils for cancelling noise components by performing a correction process in directions of three axes that are X, Y, and Z axes when an environmental magnetic field such as geomagnetism, i.e., a target magnetic field, in a space where the cell 4 is located, is detected. The magnetic-field correction unit 8 includes, for example, a first correction coil 8a wound around the X-axis direction, a second correction coil 8b wound around the Y-axis direction (second direction), and a third correction coil 8c wound around the Z-axis direction (third direction). The first, second, and third correction coils 8a, 8b, and 8c generate magnetic fields along the X-axis direction, the Y-axis direction, and the Z-axis direction, respectively, according to an electric current supplied from the current source 9.

That is, the first correction coil 8a corrects an intensity (hereinafter referred to as a “first detection intensity”) of the magnetic field of a component of the X-axis direction (hereinafter referred to as an “X-axis magnetic field”) included in the magnetic field within the cell 4 to a first correction intensity, the second correction coil 8b corrects an intensity ((hereinafter referred to as a “second detection intensity”) of the magnetic field of a component of the Y-axis direction (hereinafter referred to as a “Y-axis magnetic field”) included in the magnetic field within the cell 4 to a second correction intensity (e.g., zero), and the third correction coil 8c corrects an intensity (hereinafter referred to as a “third detection intensity”) of the magnetic field of a component of the Z-axis direction (hereinafter referred to as a “Z-axis magnetic field”) included in the magnetic field within the cell 4 to a third correction intensity (e.g., zero). The magnetic-field correction unit 8 operates to cancel an environmental magnetic field in the space where the cell 4 is located, by controlling the supply currents to the first, second, and third correction coils 8a, 8b, and 8c from the current source 9 with the control circuit 3.

The control circuit 3 executes a detection process for acquiring the intensity of a magnetic field based on an electrical signal from the photodiode 7. The control circuit 3 acquires the intensity of the magnetic field within the cell 4 in at least two directions among the X-axis direction, the Y-axis direction, and the Z-axis direction (the Y-axis direction and the Z-axis direction in the present embodiment). Specifically, the control circuit 3 derives the intensity of the magnetic field within the cell 4 based on the pump light intensity signal from the amplifier 11. For example, the control circuit 3 acquires a change in the transmittance of the pump light L, which is circularly polarized light transmitted through the cell 4, due to a change in the magnetic field within the cell 4, and derives the magnetic field intensity within the cell 4 based on a change in transmittance. The control circuit 3 outputs a derivation result to the control device 10. In the first embodiment, the control circuit 3 acquires the second detection intensity and the third detection intensity. Also, details of the detection process will be described below.

The control circuit 3 executes a correction process for applying a correction magnetic field to the magnetic field within the cell 4 by controlling the magnetic-field correction unit 8. Specifically, as a function of controlling magnetic-field correction, the control circuit 3 adjusts electric currents to be supplied to the first correction coil 8a, the second correction coil 8b, and the third correction coil 8c, based on the pump light intensity signal output from the amplifier 11, thereby adjusting the correction magnetic field. More specifically, the control circuit 3 observes a change in the pump light intensity signal while changing the electric current to be supplied to each of the first, second, and third correction coils 8a, 8b, and 8c, and adjusts each electric current to be supplied based on a change in the pump light intensity signal. Thereby, the correction of the environmental magnetic field in the three axial directions is controlled. Although the control circuit 3 executes both the detection process and the correction process in the present embodiment, a separate control circuit may be provided for each process.

More specifically, in the correction process, the control circuit 3 acquires at least two of the first detection intensity, the second detection intensity, and the third detection intensity, based on the electrical signal from the photodiode 7. Also, when one of any two intensities among the first correction intensity, the second correction intensity, and the third correction intensity is changed in the correction process, the control circuit 3 controls the magnetic-field correction unit 8 to apply the correction magnetic field so that any one of the first correction intensity, the second correction intensity, and the third correction intensity is adjusted to reduce a change in the detection intensity corresponding to the other of the two intensities (the first detection intensity when the other intensity is the first correction intensity, the second detection intensity when the other intensity is the second correction intensity, and the third detection intensity when the other intensity is the third correction intensity).

In the first embodiment, the control circuit 3 detects the second detection intensity and the third detection intensity based on the electrical signal from the photodiode 7 in the correction process. When one of the two intensities, i.e., the second correction intensity and the third correction intensity, is changed, the control circuit 3 controls the magnetic-field correction unit 8 to apply a correction magnetic field so that the first correction intensity is adjusted to reduce a change in the detection intensity corresponding to the other of the two intensities (the second detection intensity corresponding to the second correction intensity or the third detection intensity corresponding to the third correction intensity). For example, when an electric current to be supplied to the second correction coil 8b is controlled to change the second correction intensity in the correction process, the control circuit 3 controls the electric current to be supplied to the first correction coil 8a so that the first correction intensity is adjusted to reduce the change in the third detection intensity. Also, details of the correction process will be described below.

The control circuit 3 decides operating conditions (driving conditions) of the pump laser light source 6. Specifically, the control circuit 3 controls the wavelength of the pump light L by controlling the temperature of the pump laser light source 6 (e.g., the temperature of the laser element inside the pump laser light source 6). For example, the control circuit 3 adjusts the wavelength of the pump light L to the absorption wavelength of the alkali metal sealed within the cell 4.

As shown in FIG. 1, the control circuit 3 includes a cell temperature processing unit 31, a laser temperature control unit 32, a magnetic-field control unit 33, and a signal processing unit 34. The functions of functional units of the control circuit 3 will be described in detail below.

The cell temperature processing unit 31 adjusts the internal temperature of the cell 4. Specifically, the cell temperature processing unit 31 receives an instruction (start trigger) to adjust the internal temperature of the cell 4 from the control device 10 and starts control for adjusting the internal temperature of the cell 4. Based on a measurement signal (RTD resistance value) from a temperature sensor (not shown) that measures the internal temperature of the cell 4, the cell temperature processing unit 31 controls an electric current to be supplied from the heater control circuit 12 to the heater 5, for example, according to proportional integral differential (PID) control, so that the internal temperature of the cell 4 becomes a predetermined temperature (e.g., 180° C.).

The laser temperature control unit 32 adjusts the temperature of the pump laser light source 6. Specifically, the laser temperature control unit 32 receives an instruction (start trigger) to adjust the temperature of the pump laser light source 6 from the control device 10, and starts a process for controlling the temperature of the pump laser light source 6. The control circuit 3 adjusts the temperature of the pump laser light source 6 to a predetermined temperature, for example, according to PID control, based on a measurement signal (RTD resistance value) from a temperature sensor (not shown) that measures the temperature of the pump laser light source 6 and the electrical signal output from the photodiode 7. The predetermined temperature is the temperature of the pump laser light source 6 at which the wavelength of the pump light L matches the absorption wavelength of the alkali metal sealed within the cell 4.

The magnetic-field control unit 33 executes a correction process for correcting the magnetic field within the cell 4. Specifically, the magnetic-field control unit 33 receives an instruction (start trigger) to execute the correction process from the control device 10 and starts the correction process. The magnetic-field control unit 33 controls electric currents to be supplied to the first correction coil 8a, the second correction coil 8b, and the third correction coil 8c of the current source 9 so that the first detection intensity is adjusted to the first correction intensity, the second detection intensity is adjusted to the second correction intensity, and the third detection intensity is adjusted to the third correction intensity. In this way, the first correction intensity is a target value when the first detection intensity is corrected, the second correction intensity is a target value when the second detection intensity is corrected, and the third correction intensity is a target value when the third detection intensity is corrected.

The signal processing unit 34 executes a detection process for acquiring the magnetic field intensity within the cell 4. Specifically, the signal processing unit 34 receives an instruction (start trigger) to execute the detection process from the control device 10 and starts the detection process. The signal processing unit 34 acquires an electrical signal from the photodiode 7. Based on the electrical signal output from the photodiode 7, the signal processing unit 34 derives the magnetic field intensity within the cell 4 and outputs a derivation result to an external device such as the control device 10. In the first embodiment, the signal processing unit 34 derives the second detection intensity and the third detection intensity.

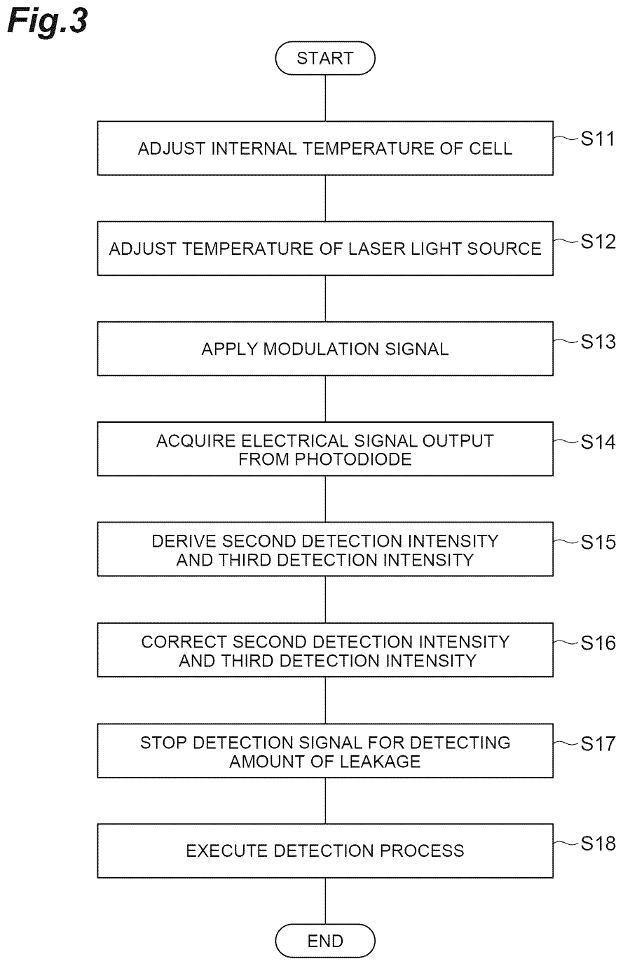

Next, a magnetic field detection method using the magnetic sensor module 1 according to the first embodiment will be described. FIG. 3 is a flowchart showing an example of a process of the magnetic field detection method including the magnetic-field correction method according to the first embodiment. When a user using the magnetic detection system 100 inputs an instruction to start the processing of the magnetic field detection method to the control device 10, the following process of the magnetic field detection method (steps S11 to S18) is initiated. First, the control circuit 3 adjusts the internal temperature of the cell 4 (step S11). Subsequently, the control circuit 3 adjusts the temperature of the pump laser light source 6 (step S12).

Subsequently, the control circuit 3 executes a correction process (steps S13 to S17: correction steps). Specifically, first, the control circuit 3 applies a modulation signal to the magnetic-field correction unit 8 (step S13). More specifically, the control circuit 3 applies a first modulation signal to the first correction coil 8a, applies a second modulation signal G2 to the second correction coil 8b, and applies a third modulation signal G3 to the third correction coil 8c. In the first embodiment, the first modulation signal includes a DC signal for correcting the X-axis magnetic field. The DC signal is a direct current and is, for example, an electric current having a frequency of zero.

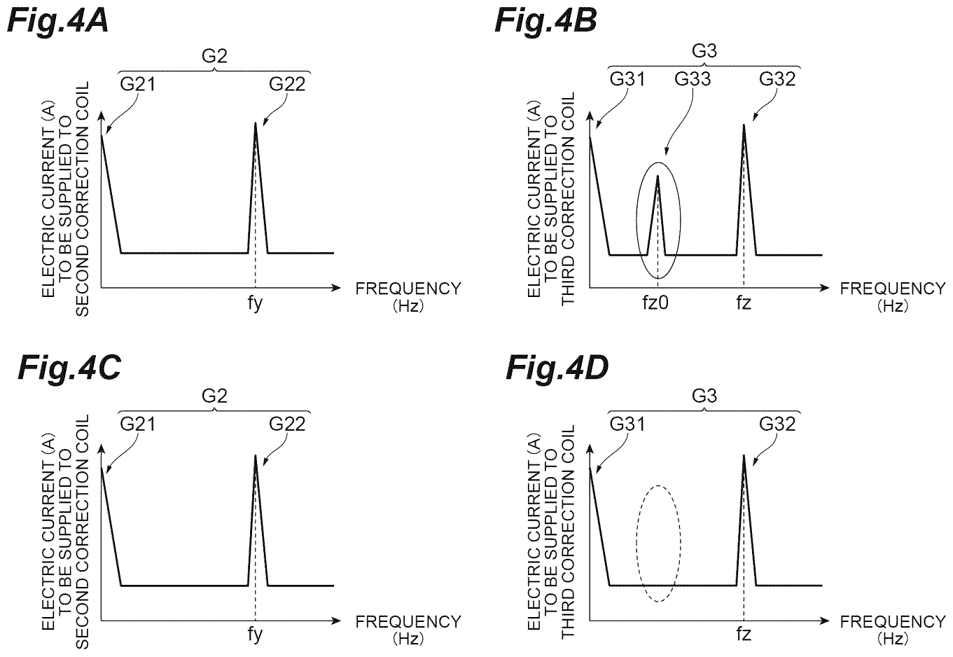

FIGS. 4A and 4C are graphs showing the second modulation signal G2. FIGS. 4B and 4D are graphs showing the third modulation signal G3. In FIGS. 4A, 4B, 4C, and 4D, the horizontal axis represents a frequency and the vertical axis represents an electric current intensity. The second modulation signal G2 (a spectrum of the electric current applied to the second correction coil 8b) includes a DC signal G21 for correcting the Y-axis magnetic field, and a lock-in signal G22 for detecting the Y-axis magnetic field. The DC signal G21 is similar to the above-described DC signal. The lock-in signal G22 is a signal having a frequency fy.

The third modulation signal G3 (a spectrum of the electric current applied to the third correction coil 8c) includes a DC signal G31 for correcting the Z-axis magnetic field, a lock-in signal G32 for detecting the Z-axis magnetic field, and a detection signal G33 for detecting an amount of leakage of the magnetic field of the component of the Z-axis direction included in the correction magnetic field into the Y direction. The DC signal G31 is similar to the above-described DC signal. The lock-in signal G32 is a signal having a frequency fz. In the present embodiment, the frequency fz may be different from or the same as the frequency fy. The intensity (amplitude) of the detection signal G33 is constant.

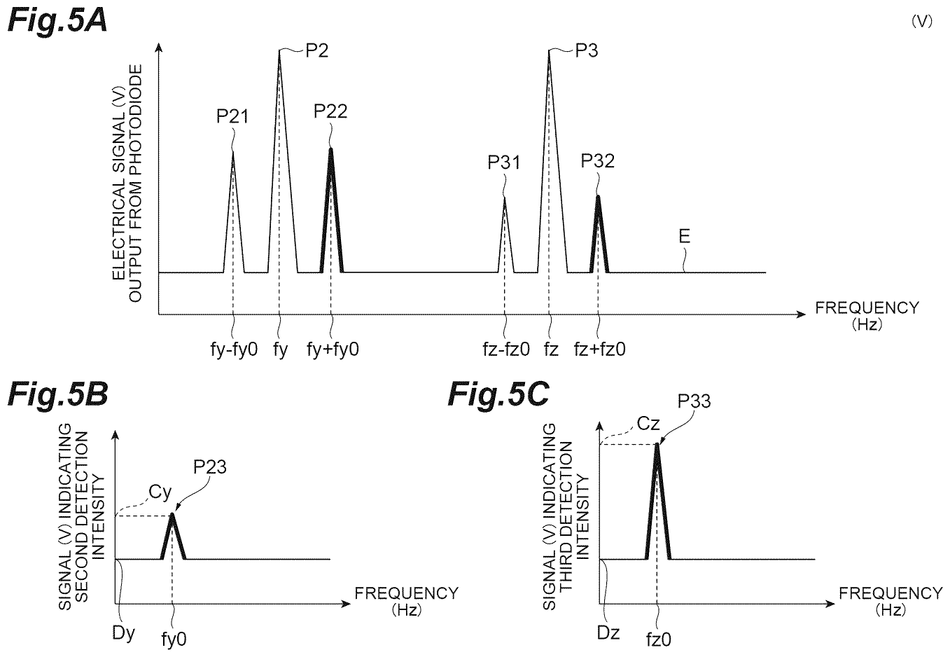

Subsequently, the control circuit 3 acquires an electrical signal output from the photodiode 7 (step S14). FIG. 5A is a graph showing a spectral waveform of the electrical signal output from the photodiode 7. In FIG. 5A, the horizontal axis represents a frequency and the vertical axis represents a magnitude of a voltage. As shown in FIG. 5A, the electrical signal E (pump light intensity signal) output from the photodiode 7 is a mixture of two components of a signal indicating a magnetic field generated by the magnetic-field correction unit 8 according to the above-described modulation signal and a signal indicating a measurement result of the magnetic field within the cell 4.

The spectral waveform of the electrical signal E includes two central pulses P2 and P3, and four mixed pulses P21, P22, P31, and P32. The central pulse P2 is a signal corresponding to a modulated magnetic field generated by the magnetic-field correction unit 8 according to the lock-in signal G22. The central pulse P3 is a signal corresponding to the modulated magnetic field generated by the magnetic-field correction unit 8 according to the lock-in signal G32. The frequency of the central pulse P2 is less than that of the central pulse P3. The central frequencies of the two central pulses P2 and P3 are the frequencies fy and fz of the lock-in signals G22 and G32, respectively.

The two mixed pulses P21 and P22 are sideband signals of signal components corresponding to the Y-axis magnetic field superimposed on the modulated magnetic field generated from the magnetic-field correction unit 8 according to the lock-in signal G22 generated from the magnetic-field correction unit 8. The central wavelength of the mixed pulse P21 is a frequency obtained by subtracting the frequency fy0 of the signal corresponding to the Y-axis magnetic field from the frequency fy of the lock-in signal G22 (fy−fy0 as shown in FIG. 5A). The central frequency of the mixed pulse P22 is a frequency obtained by adding the frequency fy0 of the signal corresponding to the Y-axis magnetic field to the frequency fy of the lock-in signal G22 (fy+fy0 as shown in FIG. 5A). Also, in FIG. 5A, the Z-axis magnetic field leaks into the Y-axis direction, such that the Y-axis magnetic field is generated, and therefore fy0=fz0.

The two mixed pulses P31 and P32 are sideband signals of signal components corresponding to the Z-axis magnetic field superimposed on the modulated magnetic field generated from the magnetic-field correction unit 8 according to the lock-in signal G32 generated from the magnetic-field correction unit 8. The central frequency of the mixed pulse P31 is a frequency obtained by subtracting the frequency fz0 of the signal corresponding to the Z-axis magnetic field from the frequency fz of the lock-in signal G32 (fz−fz0 as shown in FIG. 5A). The central frequency of the mixed pulse P32 is a frequency obtained by adding the frequency fz0 of the signal corresponding to the Z-axis magnetic field to the frequency fz of the lock-in signal G32 (fz+fz0 as shown in FIG. 5A).

Subsequently, based on the electrical signal, the control circuit 3 derives the second detection intensity and the third detection intensity (step S15). FIG. 5B is a graph showing the second detection intensity, and FIG. 5C is a graph showing the third detection intensity. In FIGS. 5B and 5C, the horizontal axis represents a frequency and the vertical axis represents the second detection intensity or the third detection intensity. As shown in FIG. 5B, the control circuit 3 demodulates the two mixed pulses P21 and P22 included in the spectral waveform of the electrical signal E, and derives a measurement pulse P23 based on the intensities of the two demodulated mixed pulses P21 and P22. A maximum intensity Cy of the measurement pulse P23 is a numerical value indicating the leakage of the Z-axis magnetic field generated from the third correction coil 8c to which the detection signal G33 has been applied, into the Y-axis direction. A direct current component Dy of the measurement pulse P23 is a numerical value indicating a direct current component of the Y-axis magnetic field. The control circuit 3 demodulates the two mixed pulses P31 and P32 included in the spectral waveform of the electrical signal E, and derives a measurement pulse P33 based on intensities of the two demodulated mixed pulses P31 and P32. A maximum intensity Cz of the measurement pulse P33 is a numerical value indicating the Z-axis magnetic field generated from the third correction coil 8c to which the detection signal G33 has been applied. A direct current component Dz of the measurement pulse P33 is a numerical value indicating the direct current component of the Z-axis magnetic field.

As in steps S14 and S15, the control circuit 3 acquires an intensity of a magnetic field within the cell in at least two of the first, second, and third directions (i.e., at least two of the first detection intensity, the second detection intensity, and the third detection intensity) based on the electrical signal E from the photodiode 7 in the correction process. For example, in steps S14 and S15, the control circuit 3 acquires the second detection intensity and the third detection intensity based on the electrical signal E from the photodiode 7. For example, by using lock-in detection, the electrical signal E output from a single photodiode 7 can be separated into a magnetic field signal indicating the Y-axis magnetic field and a magnetic field signal indicating the Z-axis magnetic field, and each of the Y-axis magnetic field and the Z-axis magnetic field can be measured. In other words, by using lock-in detection, the magnetic sensor 2 having only one photodiode 7 can be used as a two-axis sensor.

Subsequently, the control circuit 3 executes first control for correcting the first detection intensity, second control for correcting the second detection intensity, and third control for correcting the third detection intensity (step S16). The control circuit 3 executes the first control, the second control, and the third control simultaneously. Also, the control circuit 3 may execute the first control, the second control, and the third control separately in this order.

The first control is a process as follows. First, when an electric current to be supplied to the third correction coil 8c is controlled so that the third correction intensity is changed (e.g., when an electric current to be supplied to the third correction coil 8c is controlled to change the third detection intensity to the changed third correction intensity after the third correction intensity is changed), the control circuit 3 derives a change occurring in the second detection intensity as follows. First, in FIG. 5C, a magnetic field of a component of the Z-axis direction generated by applying the detection signal G33 to the third correction coil 8c is observed by a peak of the measurement pulse P33. On the other hand, in FIG. 5B, an amount of leakage in which a magnetic field of a component of the Z-axis direction generated by applying the detection signal G33 to the third correction coil 8c leaks into the Y-axis direction is observed by a peak of the measurement pulse P23. In view of this, an evaluation value Czy of the leakage of the magnetic field of the component of the Z-axis direction into the Y-axis direction is defined as (maximum intensity Cy of measurement pulse P23)/(maximum intensity Cz of measurement pulse P33). The control circuit 3 derives this evaluation value Czy as “a change occurring in the second detection intensity when an electric current to be supplied to the third correction coil 8c is controlled to change the third correction intensity.” In other words, after separating measurement pulses from the electrical signal E output from the photodiode 7, the control circuit 3 calculates a ratio of the maximum values of the measurement pulses measured in each axial direction.

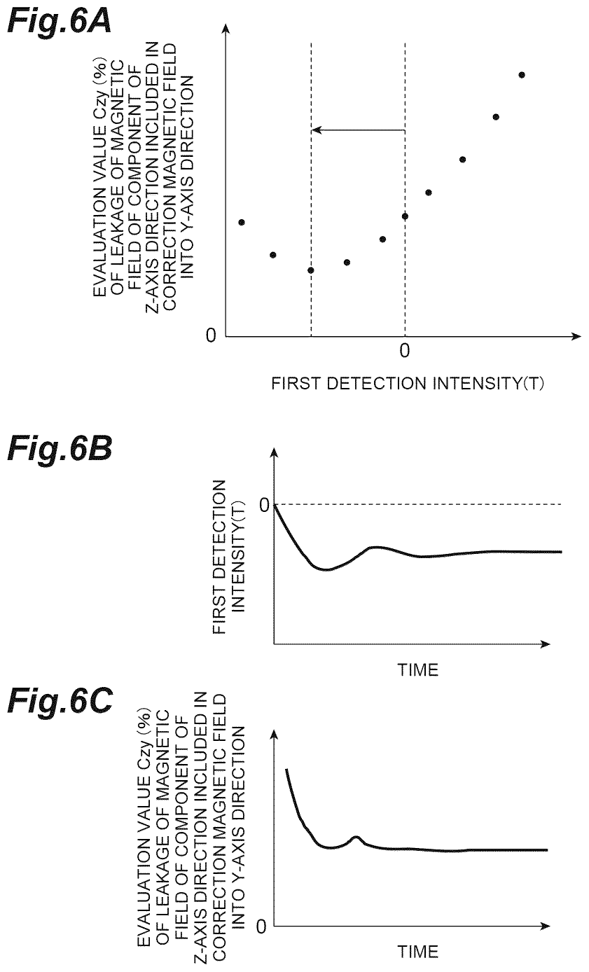

The control circuit 3 controls an electric current to be supplied to the first correction coil 8a so that the first correction intensity is adjusted to reduce the change in the second detection intensity when an electric current to be supplied to the third correction coil 8c is controlled to change the third correction intensity. FIG. 6A is a diagram showing a relationship between the evaluation value Czy and the first detection intensity. In FIG. 6A, the horizontal axis represents the first detection intensity (T) (more specifically, a direct current component of the first detection intensity) and the vertical axis represents the evaluation value Czy. As shown in FIG. 6A, by adjusting the first correction intensity so that the evaluation value Czy is reduced, the first detection intensity is reduced by the control circuit 3. In this case, the first detection intensity deviates from zero, but is not limited thereto. The first detection intensity may be zero. For example, as shown in FIGS. 6B and 6C, the control circuit 3 changes the direct current component of the electric current to be supplied to the first correction coil 8a while applying feedback so that the evaluation value Czy reaches a minimum value. In FIG. 6B, the horizontal axis represents time and the vertical axis represents the first detection intensity (more specifically, the direct current component of the first detection intensity). In FIG. 6C, the horizontal axis represents time and the vertical axis represents the evaluation value Czy.

As described above, the control circuit 3 controls the magnetic-field correction unit 8 to apply a correction magnetic field so that the first correction intensity is adjusted to reduce a change in the second detection intensity when the third correction intensity is changed, but the present invention is not limited thereto. For example, the control circuit 3 may control the magnetic-field correction unit 8 to apply a correction magnetic field so that the first correction intensity is adjusted to reduce a change in the third detection intensity when the second correction intensity is changed.

The second control is a process as follows. The control circuit 3 controls an electric current to be supplied to the second correction coil 8b so that the second detection intensity is reduced. Specifically, the control circuit 3 adjusts the electric current to be supplied to the second correction coil 8b so that the second detection intensity becomes zero. For example, the control circuit 3 changes the direct current component of the electric current to be supplied to the second correction coil 8b while applying feedback so that the intensity of the direct current component of the Y-axis magnetic field (Dy shown in FIG. 5B) becomes zero.

The third control is a process as follows. The control circuit 3 controls an electric current to be supplied to the third correction coil 8c so that the third detection intensity is reduced. Specifically, the control circuit 3 adjusts the electric current to be supplied to the third correction coil 8c so that the third detection intensity becomes zero. For example, the control circuit 3 changes a direct current component of an electric current to be supplied to the third correction coil 8c while applying feedback so that the intensity of the direct current component of the Z-axis magnetic field (Dz shown in FIG. 5C) becomes zero.

Subsequently, the detection signal for detecting the amount of leakage is stopped by the control circuit 3 (step S17). Specifically, as shown in FIGS. 4C and 4D, the second modulation signal G2 and the third modulation signal G3 are set to a state in which the detection signal for detecting the amount of leakage is not included. For example, the third modulation signal G3 is set to a state in which the detection signal G33 is not included.

In this way, the correction process is executed by the control circuit 3. Finally, the detection process for the measurement target is executed by the control circuit 3 (step S18). Specifically, the control circuit 3 acquires an electrical signal E from the photodiode 7, and derives the second detection intensity and the third detection intensity, each of which represents the intensity of the magnetic field indicated by the measurement target, based on the electrical signal E.

According to the magnetic sensor module 1 and the magnetic-field correction method of the first embodiment described above, when one of two of the first correction intensity, the second correction intensity, and the third correction intensity is changed, a correction magnetic field is applied so that one of the first correction intensity, the second correction intensity, and the third correction intensity is adjusted to reduce the change in the detection intensity corresponding to the other of the two intensities. Thereby, it is possible to reduce the amount of leakage of the magnetic field of the component of a predetermined direction included in the correction magnetic field into another direction orthogonal to the predetermined direction (e.g., the evaluation value Czy of the leakage of the magnetic field of the component of the Z-axis direction included in the correction magnetic field into the Y direction). For example, when the third detection intensity is changed, the correction magnetic field is applied so that the first detection intensity is adjusted to reduce a change occurring in the second detection intensity. In this case, it is possible to reduce the amount of leakage of the magnetic field of the component of a predetermined direction included in the correction magnetic field into another direction and the amount of leakage of the magnetic field of the component of the other direction included in the correction magnetic field into the predetermined direction (e.g., the evaluation value Czy). Thereby, it is possible to accurately detect the magnetic field within the cell 4.

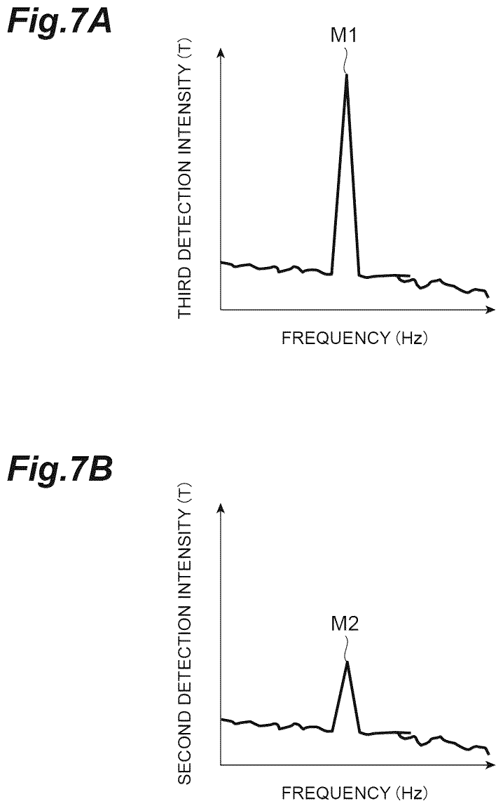

More specifically, the present inventors have obtained the knowledge that a magnetic field of a component of a predetermined direction included in the correction magnetic field generated from the magnetic-field correction unit 8 leaks into another direction orthogonal to the predetermined direction. FIG. 7A is a graph showing the second detection intensity. FIG. 7B is a graph showing the third detection intensity. In FIGS. 7A and 7B, the horizontal axis represents a frequency, and the vertical axis represents the third detection intensity or the second detection intensity. As shown in FIGS. 7A and 7B, the present inventors have obtained the knowledge that a magnetic field signal M2 is generated in the Y-axis magnetic field when a magnetic field signal M1 is applied by the control circuit 3 to correct only the Z-axis magnetic field. Here, as a result of intensive studies, the present inventors have newly found that when the first detection intensity is shifted from zero, it is possible to suppress the leakage of the magnetic field of the component of the Z-axis direction included in the correction magnetic field into the Y-axis direction (e.g., it is possible to reduce the evaluation value Czy described above to 0.05 or less) (see FIG. 6A). In view of this fact, the present inventors have conceived the configuration of the present embodiment. Also, the amount of leakage of the magnetic field of the component of the predetermined direction included in the correction magnetic field into another direction can be understood as an amount of crosstalk between the magnetic field of the component of the predetermined direction and the magnetic field of the component of the other direction. In this case, the detection signal G33 described above can also be understood as a signal for measuring the amount of crosstalk.

Moreover, in the first embodiment, when one of any two intensities among the first correction intensity, the second correction intensity, and the third correction intensity is changed in the correction process, the control circuit 3 controls the magnetic-field correction unit 8 to apply the correction magnetic field so that the first correction intensity is adjusted to reduce a change in the detection intensity corresponding to the other of the two intensities. In this case, it is possible to accurately detect the magnetic field within the cell 4.

Moreover, in the first embodiment, the control circuit 3 controls the magnetic-field correction unit 8 to apply a correction magnetic field so that the first correction intensity is adjusted to reduce a change in the third detection intensity when the second correction intensity is changed in the correction process. In this case, it is possible to reduce the amount of leakage of the magnetic field of the component of the Y-axis direction included in the correction magnetic field into the Z-axis direction and the amount of leakage of the magnetic field of the component of the Z-axis direction included in the correction magnetic field into the Y-axis direction (the evaluation value Czy). Thereby, it is possible to accurately detect the magnetic field within the cell 4.

Moreover, in the first embodiment, the magnetic-field correction unit 8 includes a first correction coil 8a for correcting the first correction intensity, a second correction coil 8b for correcting the second correction intensity, and a third correction coil 8c for correcting the third correction intensity, and the control circuit 3 executes first control for controlling an electric current to be supplied to the first correction coil 8a so that the first correction intensity is adjusted to reduce a change in the third detection intensity when an electric current to be supplied to the second correction coil 8b is controlled to change the second correction intensity in the correction process. In this case, when the magnetic-field correction unit 8 has the three coils 8a, 8b, and 8c for correcting the first correction intensity, the second correction intensity, and the third correction intensity, it is possible to accurately detect the magnetic field within the cell 4.

Moreover, in the first embodiment, the control circuit 3 further executes second control for controlling an electric current to be supplied to the second correction coil 8b to reduce the second detection intensity and third control for controlling an electric current to be supplied to the third correction coil 8c to reduce the third detection intensity in the correction process. In this case, the magnetic field within the cell can be detected in a state in which the environmental magnetic fields in the second direction and the third direction are reduced. Thereby, it is possible to accurately detect the magnetic field within the cell 4.

### Second Embodiment

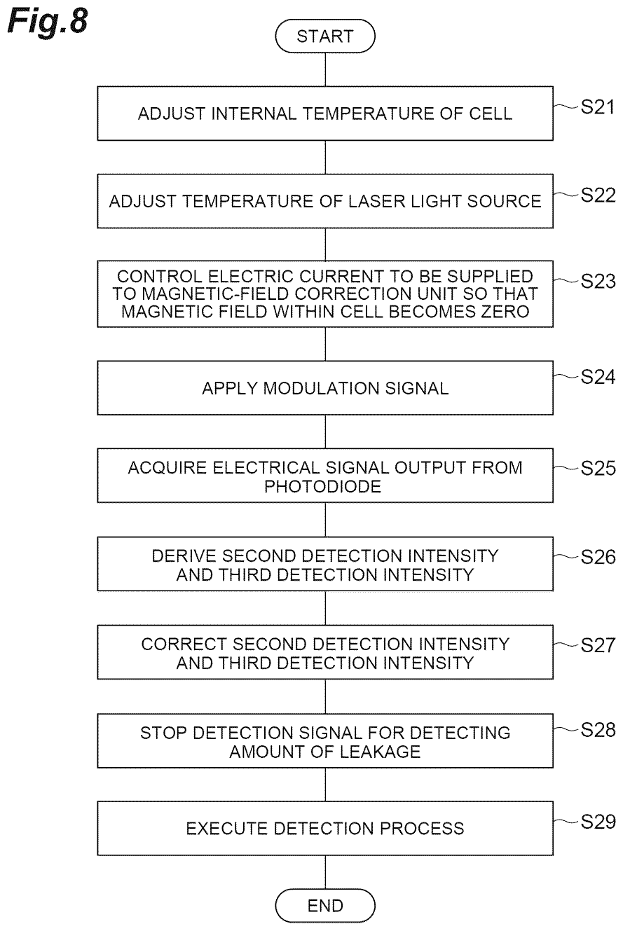

A second embodiment of the present disclosure will be described. FIG. 8 is a flowchart showing an example of a process of a magnetic field detection method including a magnetic-field correction method according to the second embodiment. The following process of the magnetic field detection method is started when an instruction to start the processing of the magnetic field detection method is input to the control device 10 by a user using the magnetic detection system 100. First, the internal temperature of the cell 4 is adjusted by the control circuit 3 (step S21). Subsequently, the temperature of the pump laser light source 6 is adjusted by the control circuit 3 (step S22).

Subsequently, the correction process (steps S23 to S28) is executed by the control circuit 3. Specifically, first, the control circuit 3 controls an electric current to be supplied to the magnetic-field correction unit 8 so that the magnetic field within the cell 4 becomes zero (step S23). More specifically, the control circuit 3 controls electric currents to be supplied to the second correction coil 8b and the third correction coil 8c so that the second correction intensity and the third correction intensity are adjusted to increase the intensity of pump light L detected by the photodiode 7 and controls an electric current to be supplied to the first correction coil 8a so that the first correction intensity is adjusted to reduce the intensity of the pump light L.

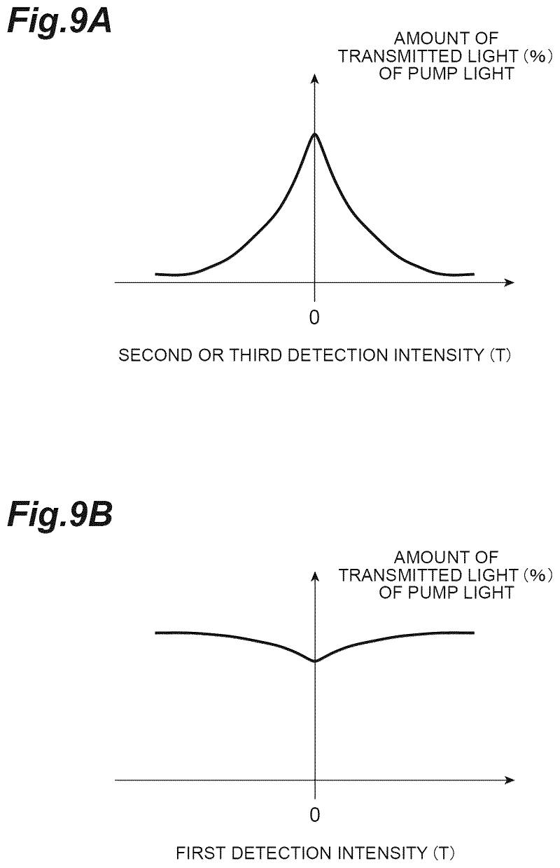

For example, the control circuit 3 derives an amount of transmitted light of the pump light L that has passed through the cell 4 based on the electrical signal output from the photodiode 7, and controls an electric current to be supplied to the magnetic-field correction unit 8 so that the magnetic field within the cell 4 becomes zero based on this amount of transmitted light. FIG. 9A is a graph showing a relationship between the second detection intensity or the third detection intensity and the amount of transmitted light of the pump light L that has passed through the cell 4, and FIG. 9B is a graph showing a relationship between the first detection intensity and the amount of transmitted light of the pump light L that has passed through the cell 4. As shown in FIGS. 9A and 9B, the change in the amount of transmitted light of the pump light L for changes in the second detection intensity and the third detection intensity is greater than the change in the amount of transmitted light of the pump light L for a change in the first detection intensity.

As shown in FIG. 9A, the control circuit 3 can set the second detection intensity (more specifically, the intensity of the direct current component of the second detection intensity) to zero by adjusting the electric current to be supplied to the second correction coil 8b so that the amount of transmitted light of the pump light L becomes maximum. The control circuit 3 can set the third detection intensity (more specifically, the intensity of the direct current component of the third detection intensity) to zero by adjusting the electric current to be supplied to the third correction coil 8c so that the amount of transmitted light of the pump light L becomes maximum. As shown in FIG. 9B, the control circuit 3 can set the first detection intensity (more specifically, the intensity of the direct current component of the first detection intensity) to zero by adjusting an electric current to be supplied to the first correction coil 8a so that the amount of transmitted light of the pump light L becomes minimum. In this way, the control circuit 3 sweeps an electric current to be supplied to each correction coil and sets an amount of electric current to be supplied to each correction coil so that the amount of transmitted light of the pump light L becomes an extreme value. Thereby, each of the first detection intensity, the second detection intensity, and the third detection intensity can be set to zero.

Subsequently, the control circuit 3 applies a modulation signal to the magnetic-field correction unit 8 (step S24). More specifically, as in step S13 of the first embodiment, the control circuit 3 inputs the first modulation signal to the first correction coil 8a, inputs the second modulation signal G2 shown in FIG. 4A to the second correction coil 8b, and inputs the third modulation signal G3 shown in FIG. 4B to the third correction coil 8c.

Subsequently, as in step S14 of the first embodiment, the control circuit 3 acquires an electrical signal output from the photodiode 7 (step S25). As in step S15 of the first embodiment, the control circuit 3 derives the second detection intensity and the third detection intensity based on the electrical signal (step S26). Also, differently from step S16 of the first embodiment, the control circuit 3 executes only the first control for correcting the first detection intensity, without executing the second control or the third control (step S27). In the first control, the control circuit 3 calculates the evaluation value Czy of leakage of the magnetic field of the component of the Z-axis direction included in the correction magnetic field into the Y-axis direction while sweeping the direct current flowing through the first correction coil 8a. Also, the control circuit 3 adjusts the direct current flowing through the first correction coil 8a so that the evaluation value Czy becomes smallest in the first control.

Subsequently, the control circuit 3 stops a detection signal for detecting the amount of leakage (step S28). More specifically, as in step S17 of the first embodiment, the second modulation signal G2 and the third modulation signal G3 are set to a state in which a detection signal for detecting an amount of leakage is not included. For example, the third modulation signal G3 is set to a state in which the detection signal G33 is not included.

In this way, the control circuit 3 executes the correction process. Finally, the control circuit 3 executes the detection process for a measurement target (step S29). More specifically, as in step S18 of the first embodiment, the control circuit 3 acquires an electrical signal E from the photodiode 7, and derives the second detection intensity and the third detection intensity, each of which represents the intensity of the magnetic field indicated by the measurement target, based on the electrical signal E.

According to the magnetic sensor module 1 and the magnetic-field correction method of the second embodiment, as in the first embodiment, it is possible to accurately detect the magnetic field within the cell 4.

Moreover, in the second embodiment, the control circuit 3 executes the first control after electric currents to be supplied to the second correction coil 8b and the third correction coil 8c are controlled so that the second correction intensity and the third correction intensity are adjusted to increase an intensity of the pump light L detected by the photodiode 7 and an electric current to be supplied to the first correction coil 8a is controlled so that the first correction intensity is adjusted to reduce the intensity of the pump light L in the correction process. In this case, in the correction process, it is possible to easily reduce an environmental magnetic field of the X-axis direction, an environmental magnetic field of the Y-axis direction, and an environmental magnetic field of the Z-axis direction. Moreover, after the environmental magnetic fields are reduced, the first control is executed. Thereby, the amount of leakage of the magnetic field of the component of the Y-axis direction included in the correction magnetic field into the Z-axis direction, and the amount of leakage of the magnetic field of the component of the Z-axis direction included in the correction magnetic field into the Y-axis direction, can be more reliably reduced.

Although various embodiments of the present invention have been described above, the present invention is not limited to the first embodiment and the second embodiment described above and the present invention may be modified or applied to other things as long as the subject matter described in the claims is not changed.

For example, the control circuit 3 acquires the second detection intensity and the third detection intensity in the first and second embodiments described above, but the present invention is not limited thereto. It is only necessary for the control circuit 3 to acquire the intensity of the magnetic field within the cell in at least two of the first direction, the second direction, and the third direction (at least two of the first detection intensity, the second detection intensity, and the third detection intensity). For example, the control circuit 3 may acquire the first detection intensity and the second detection intensity or the first detection intensity and the third detection intensity or may acquire all of the first detection intensity, the second detection intensity, and the third detection intensity.

For example, in the first and second embodiments described above, when one of the second detection intensity and the third detection intensity is changed in the correction process, the control circuit 3 controls the magnetic-field correction unit 8 to apply a correction magnetic field so that the first correction intensity is adjusted to reduce the change occurring in the other of the two intensities, but the present invention is not limited thereto. When one of any two intensities among the first detection intensity, the second detection intensity, and the third detection intensity is changed, it is only necessary for the control circuit 3 to control the magnetic-field correction unit 8 and apply a correction magnetic field so that the first correction intensity is adjusted to reduce the change occurring in the other of the two intensities.

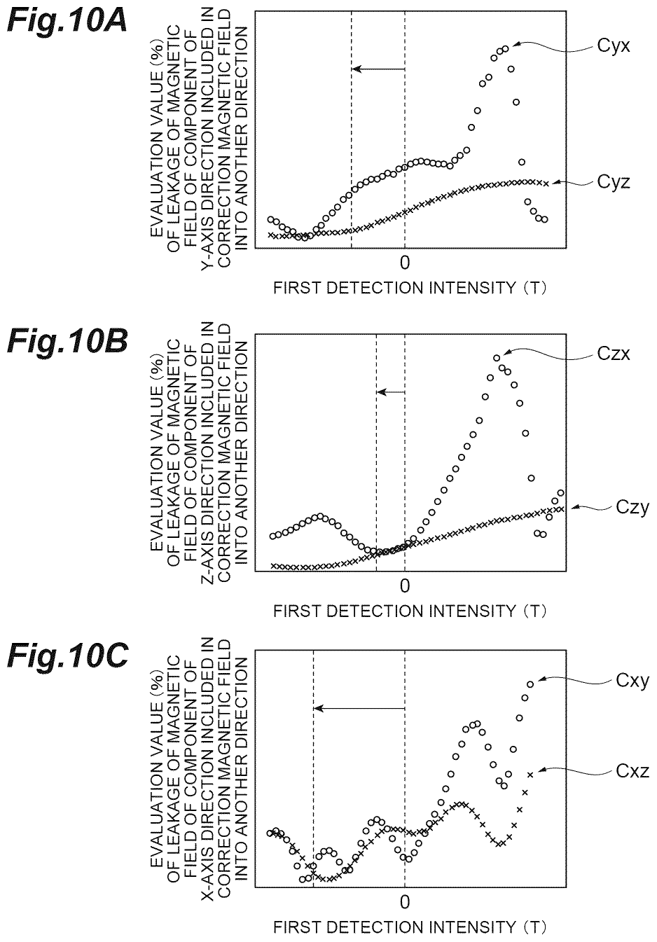

As an example, the control circuit 3 may adjust the first correction intensity so that the change occurring in the first detection intensity or the third detection intensity is reduced when the second correction intensity is changed. In this case, it is possible to reduce the evaluation values Cyx and Cyz, which represent the leakage of the magnetic field of the component of the Y-axis direction included in the correction magnetic field into other directions (the X-axis direction and the Z-axis direction). FIG. 10A is a graph showing relationships between the evaluation values Cyx and Cyz, which represent leakage of the magnetic field of the component of the Y-axis direction included in the correction magnetic field into other directions, and the first detection intensity. As shown in FIG. 10A, when the first detection intensity is shifted from zero (e.g., when the first detection intensity is shifted negatively), each of the evaluation values Cyx and Cyz can be reduced.

As an example, the control circuit 3 may adjust the first correction intensity so that the change occurring in the first detection intensity or the second detection intensity is reduced when the third correction intensity is changed. In this case, it is possible to reduce the evaluation values Czx and Czy, which represent leakage of the magnetic field of the component of the Z-axis direction included in the correction magnetic field into other directions (the X-axis direction and the Y-axis direction). FIG. 10B is a graph showing relationships between the evaluation values Czx and Czy, which represent leakage of the magnetic field of the component of the Z-axis direction included in the correction magnetic field into other directions, and the intensity of the X-axis magnetic field. As shown in FIG. 10B, when the first detection intensity is shifted from zero (e.g., the first detection intensity is shifted to a negative value), each of the evaluation values Czx and Czy can be reduced.

As an example, the control circuit 3 may adjust the first correction intensity so that the change occurring in the second detection intensity or the third detection intensity is reduced when the first correction intensity is changed. In this case, it is possible to reduce the evaluation values Cxy and Cxz, which represent leakage of the magnetic field of the component of the X-axis direction included in the correction magnetic field into other directions (the Y-axis direction and the Z-axis direction). FIG. 10C is a graph showing relationships between the evaluation values Cxy and Cxz, which represent leakage of the magnetic field of the component of the Y-axis direction included in the correction magnetic field into other directions, and the first detection intensity. As shown in FIG. 10C, when the first detection intensity is shifted from zero (e.g., when the first detection intensity is shifted to a negative value), each of the evaluation values Cxy and Cxz can be reduced.

Although the control circuit 3 controls the magnetic-field correction unit 8 to apply a correction magnetic field so that the first correction intensity is adjusted in the correction process, for example, in the first and second embodiments described above, the present invention is not limited thereto. As an example, the control circuit 3 may control the magnetic-field correction unit 8 to apply a correction magnetic field so that the second correction intensity or the third correction intensity is adjusted in the correction process. Also, in this case, the above-described evaluation values Cyx, Cyz, Czx, Czy, Cxy, and Cxz can be reduced.

Although the magnetic-field correction unit 8 includes the first correction coil 8a, the second correction coil 8b, and the third correction coil 8c, for example, in the first and second embodiments described above, the present invention is not limited thereto. As an example, it is only necessary for the magnetic-field correction unit 8 to correct the magnetic field within the cell 4.

In the above-described first aspect of the embodiment, preferably, when one of any two intensities among the first correction intensity, the second correction intensity, and the third correction intensity is changed in the correction process, the control unit controls the magnetic-field correction unit to apply a correction magnetic field so that the first correction intensity is adjusted to reduce the change in the detection intensity corresponding to the other of the two intensities. In this case, it is possible to accurately detect the magnetic field within the cell.

Moreover, in the above-described first aspect, preferably, the control unit controls the magnetic-field correction unit to apply a correction magnetic field so that the first correction intensity is adjusted to reduce the change in the third detection intensity when the second correction intensity is changed in the correction process. In this case, the leakage of the magnetic field of the component of the second direction included in the correction magnetic field into the third direction and the leakage of the magnetic field of the component of the third direction included in the correction magnetic field into the second direction can be reduced. Thereby, it is possible to accurately detect the magnetic field within the cell.

In the above-described first aspect, preferably, the magnetic-field correction unit includes a first correction coil configured to correct the first correction intensity, a second correction coil configured to correct the second correction intensity, a third correction coil configured to correct the third correction intensity, and the control unit executes first control for controlling an electric current to be supplied to the first correction coil so that the first correction intensity is adjusted to reduce the change in the third detection intensity when an electric current to be supplied to the second correction coil is controlled to change the second correction intensity in the correction process. In this case, when the magnetic-field correction unit includes three coils for correcting the first, second, and third correction intensities, it is possible to accurately detect the magnetic field within the cell.

Moreover, in the above-described first aspect, preferably, the control unit further executes second control for controlling the electric current to be supplied to the second correction coil so that the second detection intensity is reduced and third control for controlling the electric current to be supplied to the third correction coil so that the third detection intensity is reduced in the correction process. In this case, it is possible to detect the magnetic field within the cell in a state in which the environmental magnetic field in the second direction and the environmental magnetic field in the third direction are reduced. Thereby, it is possible to accurately detect the magnetic field within the cell.

In the above-described first aspect, preferably, the control unit executes the first control after electric currents to be supplied to the second correction coil and the third correction coil are controlled so that the second correction intensity and the third correction intensity are adjusted to increase an intensity of the laser light detected by the light detection unit and an electric current to be supplied to the first correction coil is controlled so that the first correction intensity is adjusted to reduce the intensity of the laser light in the correction process. In this case, in the correction process, the environmental magnetic field in the first direction, the environmental magnetic field in the second direction, and the environmental magnetic field in the third direction can be easily reduced. Moreover, after the environmental magnetic fields are reduced, the first control is executed. Thereby, an amount of leakage of the magnetic field of the component of the second direction included in the correction magnetic field into the third direction and an amount of leakage of the magnetic field of the component of the third direction included in the correction magnetic field into the second direction can be reduced more reliably.

A magnetic sensor module of an embodiment may be [1] “a magnetic sensor module comprising: a cell in which an alkali metal is sealed; a laser light source configured to emit laser light along a first direction toward the cell; a light detection unit configured to detect the laser light that has passed through the cell; a magnetic-field correction unit configured to correct a magnetic field within the cell; and a control unit configured to acquire an intensity of the magnetic field within the cell in at least two of the first direction, a second direction orthogonal to the first direction, and a third direction orthogonal to both the first and second directions and execute a correction process by controlling the magnetic-field correction unit to apply a correction magnetic field to the magnetic field, based on an electrical signal from the light detection unit, wherein the control unit acquires at least two of a first detection intensity of the magnetic field in the first direction, a second detection intensity of the magnetic field in the second direction, and a third detection intensity of the magnetic field in the third direction based on the electrical signal from the light detection unit in the correction process, and wherein, when one of any two intensities among a first correction intensity of the magnetic field in the first direction, a second correction intensity of the magnetic field in the second direction, and a third correction intensity of the magnetic field in the third direction is changed in the correction process, the control unit controls the magnetic-field correction unit to apply the correction magnetic field so that any one of the first correction intensity, the second correction intensity, and the third correction intensity is adjusted to reduce a change in the detection intensity in a direction corresponding to the other of the two intensities.”

A magnetic sensor module of an embodiment may be [2] “the magnetic sensor module according to the above-described [1], wherein the control unit controls the magnetic-field correction unit to apply the correction magnetic field so that the first correction intensity is adjusted to reduce the change in the detection intensity corresponding to the other of the two intensities when the one of any two intensities among the first correction intensity, the second correction intensity, and third correction intensity is changed in the correction process.”

A magnetic sensor module of an embodiment may be [3] “the magnetic sensor module according to the above-described [2], wherein the control unit controls the magnetic-field correction unit to apply the correction magnetic field so that the first correction intensity is adjusted to reduce the change in the third detection intensity when the second correction intensity is changed in the correction process.”

A magnetic sensor module of an embodiment may be [4] “the magnetic sensor module according to the above-described [3], wherein the magnetic-field correction unit includes: a first correction coil configured to correct the first correction intensity; a second correction coil configured to correct the second correction intensity, and a third correction coil configured to correct the third correction intensity, and wherein the control unit executes first control for controlling an electric current to be supplied to the first correction coil so that the first correction intensity is adjusted to reduce the change in the third detection intensity when an electric current to be supplied to the second correction coil is controlled to change the second correction intensity in the correction process.”

A magnetic sensor module of an embodiment may be [5] “the magnetic sensor module according to the above-described [4], wherein the control unit further executes second control for controlling the electric current to be supplied to the second correction coil so that the second detection intensity is reduced and third control for controlling the electric current to be supplied to the third correction coil so that the third detection intensity is reduced in the correction process.”

A magnetic sensor module of an embodiment may be [6] “the magnetic sensor module according to the above-described [4], wherein the control unit executes the first control after electric currents to be supplied to the second correction coil and the third correction coil are controlled so that the second correction intensity and the third correction intensity are adjusted to increase an intensity of the laser light detected by the light detection unit and an electric current to be supplied to the first correction coil is controlled so that the first correction intensity is adjusted to reduce the intensity of the laser light in the correction process.”

A magnetic-field correction method of an embodiment may be [7] a magnetic-field correction method of a magnetic sensor module including a cell in which an alkali metal is sealed, a laser light source configured to emit laser light along a first direction toward the cell, a light detection unit configured to detect the laser light that has passed through the cell, and a magnetic-field correction unit configured to correct a magnetic field within the cell, the magnetic-field correction method comprising: a correction step of acquiring an intensity of the magnetic field within the cell in at least two of the first direction, a second direction orthogonal to the first direction, and a third direction orthogonal to both the first and second directions and executing a correction process by controlling the magnetic-field correction unit to apply a correction magnetic field to the magnetic field, based on an electrical signal from the light detection unit, wherein the correction step includes detecting at least two of a first detection intensity of the magnetic field in the first direction, a second detection intensity of the magnetic field in the second direction, and a third detection intensity of the magnetic field in the third direction based on the electrical signal from the light detection unit, and applying, when one of any two intensities among a first correction intensity of the magnetic field in the first direction, a second correction intensity of the magnetic field in the second direction, and a third correction intensity of the magnetic field in the third direction is changed, the correction magnetic field so that any one of the first correction intensity, the second correction intensity, and the third correction intensity is adjusted to reduce a change in the detection intensity in a direction corresponding to the other of the two intensities.”

### REFERENCE SIGNS LIST

1 Magnetic sensor module, 3 Control circuit (control unit), 4 Cell, 6 Pump laser light source (laser light source), 8 Magnetic-field correction unit, 8a First correction coil, 8b Second correction coil, 8c Third correction coil, E Electrical signal, L Pump light (laser light)

What is claimed is:

1. A magnetic sensor module comprising:
a cell in which an alkali metal is sealed;
a laser light source configured to emit laser light along a first direction toward the cell;
a light detection unit configured to detect the laser light that has passed through the cell;
a magnetic-field correction unit configured to correct a magnetic field within the cell; and
a control unit configured to acquire an intensity of the magnetic field within the cell in at least two of the first direction, a second direction orthogonal to the first direction, and a third direction orthogonal to both the first and second directions and execute a correction process by controlling the magnetic-field correction unit to apply a correction magnetic field to the magnetic field, based on an electrical signal from the light detection unit,
wherein the control unit acquires at least two of a first detection intensity of the magnetic field in the first direction, a second detection intensity of the magnetic field in the second direction, and a third detection intensity of the magnetic field in the third direction based on the electrical signal from the light detection unit in the correction process, and
wherein, when one of any two intensities among a first correction intensity of the magnetic field in the first direction, a second correction intensity of the magnetic field in the second direction, and a third correction intensity of the magnetic field in the third direction is changed, the control unit controls the magnetic-field correction unit to apply the correction magnetic field so that any one of the first correction intensity, the second correction intensity, and the third correction intensity is adjusted to reduce a change in the detection intensity in a direction corresponding to the other of the two intensities in the correction process.

2. The magnetic sensor module according to claim 1, wherein the control unit controls the magnetic-field correction unit to apply the correction magnetic field so that the first correction intensity is adjusted to reduce the change in the detection intensity corresponding to the other of the two intensities when the one of any two intensities among the first correction intensity, the second correction intensity, and third correction intensity is changed in the correction process.

3. The magnetic sensor module according to claim 2, wherein the control unit controls the magnetic-field correction unit to apply the correction magnetic field so that the first correction intensity is adjusted to reduce the change in the third detection intensity when the second correction intensity is changed in the correction process.

4. The magnetic sensor module according to claim 3,
wherein the magnetic-field correction unit includes:
a first correction coil configured to correct the first correction intensity;
a second correction coil configured to correct the second correction intensity, and
a third correction coil configured to correct the third correction intensity, and
wherein the control unit executes first control for controlling an electric current to be supplied to the first correction coil so that the first correction intensity is adjusted to reduce the change in the third detection intensity when an electric current to be supplied to the second correction coil is controlled to change the second correction intensity in the correction process.

5. The magnetic sensor module according to claim 4, wherein the control unit further executes second control for controlling the electric current to be supplied to the second correction coil so that the second detection intensity is reduced and third control for controlling the electric current to be supplied to the third correction coil so that the third detection intensity is reduced in the correction process.

6. The magnetic sensor module according to claim 4, wherein the control unit executes the first control after electric currents to be supplied to the second correction coil and the third correction coil are controlled so that the second correction intensity and the third correction intensity are adjusted to increase an intensity of the laser light detected by the light detection unit and an electric current to be supplied to the first correction coil is controlled so that the first correction intensity is adjusted to reduce the intensity of the laser light in the correction process.

7. A magnetic-field correction method of a magnetic sensor module including a cell in which an alkali metal is sealed, a laser light source configured to emit laser light along a first direction toward the cell, a light detection unit configured to detect the laser light that has passed through the cell, and a magnetic-field correction unit configured to correct a magnetic field within the cell, the magnetic-field correction method comprising:
a correction step of acquiring an intensity of the magnetic field within the cell in at least two of the first direction, a second direction orthogonal to the first direction, and a third direction orthogonal to both the first and second directions and executing a correction process by controlling the magnetic-field correction unit to apply a correction magnetic field to the magnetic field, based on an electrical signal from the light detection unit,
wherein the correction step includes
acquiring at least two of a first detection intensity of the magnetic field in the first direction, a second detection intensity of the magnetic field in the second direction, and a third detection intensity of the magnetic field in the third direction based on the electrical signal from the light detection unit, and
applying, when one of any two intensities among a first correction intensity of the magnetic field in the first direction, a second correction intensity of the magnetic field in the second direction, and a third correction intensity of the magnetic field in the third direction is changed, the correction magnetic field so that any one of the first correction intensity, the second correction intensity, and the third correction intensity is adjusted to reduce a change in the detection intensity in a direction corresponding to the other of the two intensities.
